(19) United States
(12) Patent Application Publication
(10) Pub. No.: US 2006/0267113 A1
(43) Pub. Date: Nov. 30, 2006

(54) Semiconductor device structure and method therefor

(76) Inventors: Philip J. Tobin, Austin, TX (US); Cristiano Capasso, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/140,161

(22) Filed: May 27, 2005

(51) Int. Cl. H01L 29/76

(52) U.S. Cl. 257/408

(57) ABSTRACT

A device structure and method for forming the device structure has a semiconductor substrate with an overlying first metal oxide layer, an overlying intermediate layer with a first metal and either nitrogen or carbon, and an overlying second metal oxide layer. Oxygen is then provided to the intermediate layer. The oxygen has the effect of changing the intermediate layer from a conducting layer to a dielectric layer. A final device may then be formed, for example, by forming a gate and two current electrodes.

### FIELD OF THE INVENTION

This invention relates to integrated circuits, and more particularly to forming a gate dielectric for transistors of the integrated circuit.

### BACKGROUND OF THE INVENTION

Gate dielectrics have historically been silicon oxide, but as gate dielectric thickness has been decreased, current leakage from the gate to the channel has increased. In order to overcome this leakage problem, other materials have been developed for the gate dielectric. The materials are preferably high k dielectrics so they can be sufficiently thick to prevent the excessive current leakage while retaining sufficient electrical coupling between the gate and the channel for effective transistor operation. A variety of possible materials have been developed for this material, particularly metal oxides. One problem of this type of material is that it has been found to be a poor barrier to oxygen diffusion, which is important in avoiding excessive silicon oxide growth underneath the metal oxide. Another problem is that defect states in the metal oxide trap charge that leads to variable transistor threshold voltages making-circuits operate inconsistently.

Other materials, such as silicon, aluminum, and nitrogen, have been added to the metal oxide to overcome these and other problems with metal oxide. These tend to add problems that may be just as bad as the problem they are solving. For example, the addition of nitrogen tends to suppress the formation of extra silicon oxide growth but also tends to degrade mobility and shift threshold voltage from the desired values. Similarly, the addition of aluminum tends to reduce oxygen diffusion but tends to degrade mobility. The addition of silicon also tends to slow down oxygen diffusion and improve mobility but lowers the dielectric constant.

Thus there is a need for a gate dielectric that overcomes or reduces one or more of these problems.

### BRIEF DESCRIPTION OF THE DRAWINGS

The foregoing and further and more specific objects and advantages of the invention will become readily apparent to those skilled in the art from the following detailed description of a preferred embodiment thereof taken in conjunction with the following drawings:

FIG. 1 is a cross section of a semiconductor structure at a stage in processing according to one embodiment;

FIG. 2 is a cross section of the semiconductor structure of FIG. 1 at a subsequent stage in processing;

FIG. 3 is a cross section of the semiconductor structure of FIG. 2 at a subsequent stage in processing;

FIG. 4 is a cross section of a semiconductor structure at a stage in processing according to another embodiment;

FIG. 5 is a cross section of the semiconductor structure of FIG. 4 at a subsequent stage in processing; and

FIG. 6 is a cross section of the semiconductor structure of FIG. 5 at a subsequent stage in processing;

### DETAILED DESCRIPTION OF THE INVENTION

In one aspect a gate dielectric for a transistor is made using a plurality of alternating layers of a first type and second type. The first type comprises a metal oxide and the second type comprises a metal layer that comprises a metal and at least one of nitrogen and carbon. Layers of the first type separate a layer or layers of the second type from the substrate and also the gate. Layers of the second type may have the effect of providing the beneficial effect of adding nitrogen by reducing oxygen diffusion but avoiding the adverse effect of reducing mobility and varying threshold voltage. A subsequent introduction of oxygen converts the second type of layer from a conductor to a dielectric. This is better understood by reference to the drawings and the following description.

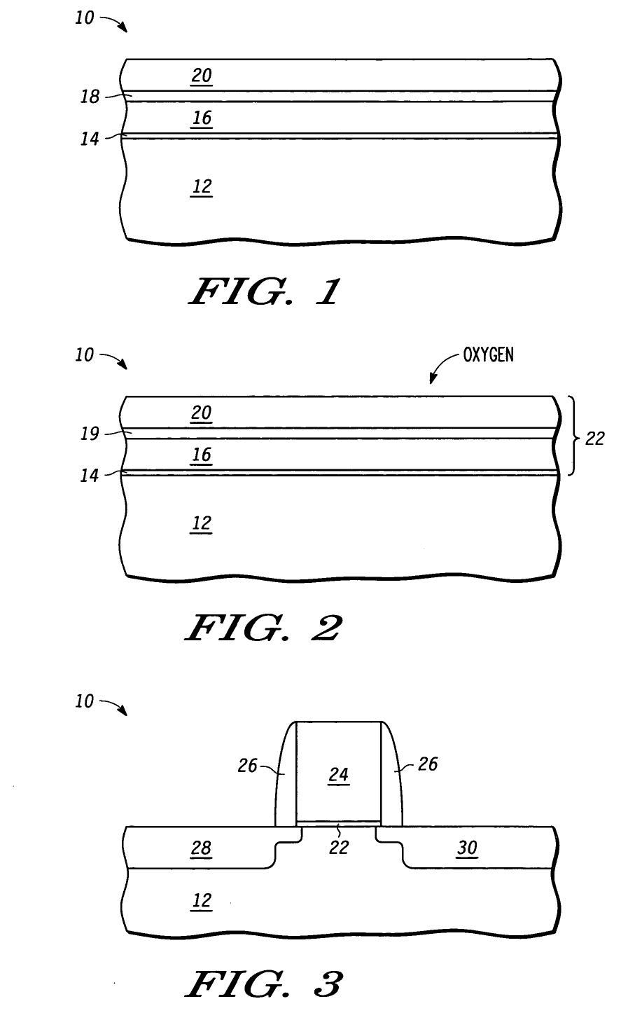

Shown in FIG. 1 is a semiconductor device 10 comprising a semiconductor substrate 12, a silicon oxide layer 14, a hafnium oxide layer 16, a titanium nitride layer 18, and a hafnium oxide layer 20. Substrate 12 is preferably silicon and is shown as a bulk silicon substrate but could also be a semiconductor on insulator (SOI) substrate. Silicon oxide layer 14 is preferably 5-10 Angstroms thick. This oxide layer is virtually unavoidable for a silicon substrate but also does provide a useful function as a transition to high k dielectric. The thickness is determined primarily two factors; the particular character of a pre-clean before the formation of hafnium oxide layer 16 and interactions with the manner of forming and processing the subsequently formed layers.

Hafnium oxide layer 16 is preferably in the range of 5 to 30 Angstroms thick and preferably deposited on silicon oxide layer 14 by chemical vapor deposition (CVD), but could also be formed by plasma-enhanced CVD (PECVD), atomic layer deposition (ALD) or sputtering, or some other technique. The layer is preferably free of impurities, particularly carbon and chlorine. Titanium nitride layer 18 is deposited on hafnium oxide layer 16 to a thickness of preferably 5-10 Angstroms preferably by sputtering but could also be done by PECVD, CVD, or ALD. The atomic concentration of nitrogen and titanium in layer 18 is preferably 1 to 1. A different concentration would be more permeable and less desirable as a barrier. Hafnium oxide layer 20 is preferably deposited on titanium nitride layer 18 in the same manner and to the same thickness range as titanium nitride layer 16 was deposited. Hafnium oxide layer 20 could also be deposited using a different technique than for hafnium oxide layer 16. For example, sputtering may be more desirable for the case in which titanium nitride layer 18 is deposited by sputtering if possible to avoid removing device structure 10 from one tool and taking it to another. An exemplary alternative to hafnium oxide is hafnium zirconium oxide. Also ALD may be preferable for all three layers 16, 18, and 20, especially in manufacturing because it would be particularly effective in precisely controlling the thickness and being able to perform all of the depositions in a single tool. Being able to perform all of the depositions in a single tool is particularly helpful in avoiding contamination at the interface between layers that is difficult to avoid when a surface is removed from a tool.

Shown in FIG. 2 is device structure 10 being exposed to an oxygen anneal. Preferably the oxygen anneal is performed in elemental oxygen (O₂) but the oxygen could also be in another form such as nitric oxide (NO), nitrous oxide (N₂O), and carbon dioxide (CO2). The temperature of the anneal is preferably 400 to 900 degrees Celsius. The higher temperature in this range is for the thicker examples of titanium nitride layer 18. The oxygen anneal may also be formed with energy activation such as plasma activation or optical activation. The oxygen anneal is for converting titanium nitride layer 18, which is conductive, to a titanium oxynitride layer 19, which is a dielectric. During this anneal that forms titanium oxynitride layer 19, some titanium and nitrogen may spread from titanium nitride layer 18 to hafnium oxide layers 16 and 18. Oxide layer 14, hafnium oxide layer 16 on oxide layer 14, titanium oxynitride layer 19 on hafnium oxide layer 16, and hafnium oxide layer 20 on titanium oxynitride layer 19 comprise a gate dielectric stack 22.

Shown in FIG. 3 is device structure 10 as a completed transistor after forming a gate 24 on gate dielectric stack 22, a source/drain 28 in substrate 12 adjacent to gate 24, a source/drain 30 in substrate 30 adjacent to gate 24, and a sidewall spacer 26 around gate 24. Gate 24 is preferably a metal stack but could also be polysilicon, a single metal, or combination of metal and polysilicon or even another material such as polysilicon germanium.

In a typical hafnium oxide deposition, such as the deposition of hafnium oxide layers 16 and 20, there is a post-deposition anneal that densities the hafnium oxide and after source/drain formation, such formation of source/drains 28 and 30, there are a high temperature anneals. These anneals normally also have the effect of driving oxygen from the hafnium oxide and to the substrate to form a thicker and thus less desirable silicon oxide layer. Titanium nitride layer 19 is useful in collecting the oxygen that is diffusing. The titanium nitride layer 19 effectively provides a magnet for the diffusing oxygen due to the large free energy formation of titanium oxide compared to titanium nitride. Thus, the diffusing oxygen will diffuse toward titanium nitride layer 19 rather than toward substrate 12. Similarly, the oxygen diffusing in hafnium oxide layer 20 will go toward titanium nitride layer 16 rather than gate 24. Gate stack 22 has shown to result in a more reliable transistor than using hafnium oxide alone.

Other barriers may be effective in addition to titanium nitride. The barrier may be considered generally to be a metal in combination with one of carbon or nitrogen. Titanium carbide (TiC) for example may be effective. Nitrogen is particularly attractive for use because it has relatively small adverse effect as contaminant in small quantities. For example, a small amount of nitrogen may diffuse to the interface with silicon but will cause minimal impact. To the extent it does, it decreases mobility and shifts threshold voltage. If the effect is small, this may be acceptable. On the other hand, excess carbon in the presence of silicon may form silicon carbide which can cause device failure. Similarly, another metal than titanium may be effective in combination with nitrogen or carbon. One example of such a metal is tantalum. In the case of tantalum, silicon and nitrogen (TaSiN) can be included in the combination as the barrier. TaSiN, which is amorphous, is a better barrier than titanium nitride but is less of an attractor of diffusing oxygen.

Shown in FIG. 4 is a device structure 40 is comprising a substrate 42, a silicon oxide layer 44, and a plurality of alternating layers of hafnium oxide and titanium nitride, 46, 48, 50, 52, and 54. The layers of hafnium oxide that are shown are layers 46, 50 and 54. The layers of titanium nitride that are shown are layers 48 and 52. Substrate 42 and silicon oxide layer 44 are the same as for substrate 12 and silicon oxide layer 14 of device structure 10. Hafnium oxide layer 46 is on silicon oxide layer 44. Titanium nitride layer 48 is on hafnium oxide layer 46. Hafnium oxide layer 50 is on titanium nitride layer 48. Titanium nitride layer 52 is on hafnium oxide layer 50. Alternating layers of titanium nitride and hafnium oxide continues. The last layer of these alternating layers is hafnium oxide layer 54. The alternating layers of hafnium oxide and titanium nitride are preferably deposited by ALD. Each of these layers, with the possible exception of hafnium oxide layer 46, are preferably quite thin but at least a monolayer in order to achieve a clear interface between layers. For these materials a monolayer is about 5 Angstroms thick. ALD may be the only technique available to achieve these very thin layers, but another technique may be developed or existing techniques may be improved to be able to do this in which case they could be used. The total thickness of the plurality of alternating layers should be 15 to 40 Angstroms.

Shown in FIG. 5 is device structure 40 undergoing an oxygen anneal. This is the same anneal that is described for FIG. 2. This anneal converts titanium nitride layers 48 and 52 to titanium oxynitride layers 49 and 53, respectively. The other titanium nitride layers not specifically shown are also converted to titanium oxynitride. The resulting plurality of alternating layers of titanium oxynitride and hafnium oxide form a gate dielectric stack 56.

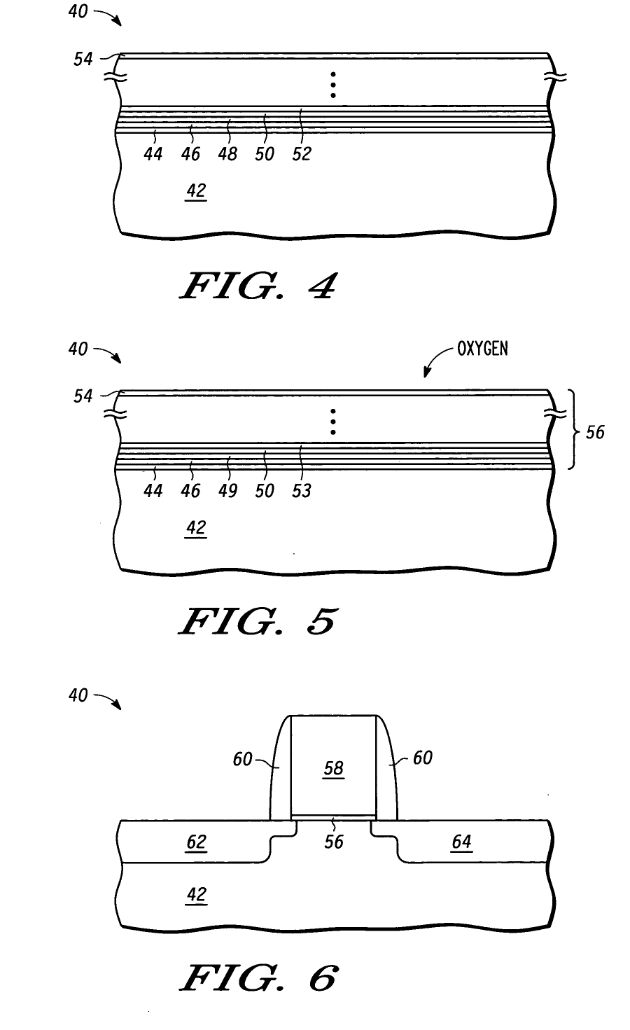

Shown in FIG. 6 is device structure 40 as a completed transistor with a gate 58 on gate dielectric 56, a sidewall spacer 60 around gate 58, a source/drain 62 in substrate 42 adjacent to gate 58 on one side of gate 58, a source/drain 64 in substrate 42 adjacent to gate 58 on an opposite side of gate 58. Source/drains function as current electrodes and gate 58 as a control electrode for a completed transistor.

The plurality of alternating layers provides for a plurality of interfaces making an additional impediment for diffusing oxygen. This also provides for improved immunity to electrical failure for a given thickness. The dielectric constant also has less variability across gate dielectric stack 56. The materials of titanium nitride and hafnium oxide may be varied as described for device structure 10.

An alternative to the oxide anneal shown in FIGS. 2 and 5 is to diffuse oxygen present in a gate after gate formation. At least in the case of P channel transistors, some of the gate materials being considered are molybdenum oxynitride (MoON), molybdenum silicon oxide (MoSiO), ruthenium oxide (RuO₂), and iridium oxide (IrO₂). If one of those is used, the oxygen anneal of FIGS. 2 and 5 is skipped and an anneal after gate formation is performed that causes outdiffusion of the oxygen in the gate. This oxygen would then react with the barrier, TiN in these described examples, to form a dielectric material. Thus the outdiffusion of the oxygen from the gate would simultaneously be prevented from reaching the substrate and causing the barrier to convert from being conductive to being a dielectric. As the barrier converts to a dielectric it also begins resisting the oxygen diffusion thus keeping the oxygen in the gate. The oxygen in the gate is important in achieving the desired work function so this impeding the outdiffusion allows for retention of the desired work function.

Various changes and modifications to the embodiments herein chosen for purposes of illustration will readily occur to those skilled in the art. For example, other metal oxides than hafnium oxide and hafnium zirconium oxide may be useful. To the extent that such modifications and variations do not depart from the spirit of the invention, they are intended to be included within the scope thereof which is assessed only by a fair interpretation of the following claims.

1. A method for forming a device structure, comprising:
providing a semiconductor substrate;
depositing a first metal oxide layer overlying the semiconductor substrate;
depositing a first intermediate layer overlying the first metal oxide layer, the first intermediate layer comprising a first metal and at least one of a group consisting of nitrogen and carbon;
depositing a second metal oxide layer overlying the first intermediate layer; and
providing oxygen to the first intermediate layer.

2. A method as in claim 1, wherein the first metal in the first intermediate layer forms a compound with at least one of a group consisting of nitrogen and carbon,

3. A method as in claim 1, wherein the first intermediate layer further comprises silicon.

4. A method as in claim 1, wherein the first intermediate layer further comprises germanium.

5. A method as in claim 1, wherein the first metal oxide layer comprises hafnium and oxygen.

6. A method as in claim 5, wherein the second metal oxide layer comprises hafnium and oxygen.

7. A method as in claim 1, wherein the first metal comprises a transition metal.

8. A method as in claim 7, wherein the transition metal comprises titanium.

9. A method as in claim 7, wherein the transition metal comprises tantalum.

10. A method as in claim 9, wherein the first intermediate layer further comprises silicon.

11. A method as in claim 1, wherein said step of providing oxygen to the first intermediate layer comprises annealing the device structure in an ambient gas, and wherein the ambient gas comprises oxygen.

12. A method as in claim 1, wherein the first metal oxide layer has a thickness within a range from 5 to 30 Angstroms.

13. A method as in claim 1, wherein said step of providing oxygen to the first intermediate layer is performed after said step of depositing the second metal oxide layer.

14. A method for forming a device structure, comprising
providing a semiconductor substrate;
depositing a first metal oxide layer overlying the semiconductor substrate;
depositing a first intermediate layer overlying the first metal oxide layer, the first intermediate layer comprising a first metal and at least one of a group consisting of nitrogen and carbon;
depositing a second metal oxide layer overlying the first intermediate layer;
providing oxygen to the first intermediate layer;
depositing a second intermediate layer overlying the second metal oxide layer, the second intermediate layer comprising a second metal and at least one of a group consisting of nitrogen and carbon;
depositing a third metal oxide layer overlying the second intermediate layer; and
providing oxygen to the second intermediate layer.

15. A method as in claim 14, wherein said step of providing oxygen to the first intermediate layer and said step of providing oxygen to the second intermediate layer are performed approximately concurrently.

16. A method as in claim 14, wherein the second intermediate layer is more permeable to oxygen than the first intermediate layer.

17. A method as in claim 14, further comprising:
forming a gate overlying the third metal oxide layer;
forming a first current electrode in the semiconductor substrate; and
forming a second current electrode in the semiconductor substrate.

18. A method for forming a device structure, comprising:
providing a semiconductor substrate;
forming a first metal oxide layer overlying the semiconductor substrate;
forming a first intermediate layer overlying the first metal oxide layer, the first intermediate layer comprising a first metal and at least one of a group consisting of nitrogen and carbon;
forming a second metal oxide layer overlying the first intermediate layer;
forming a second intermediate layer overlying the second metal oxide layer, the second intermediate layer comprising a second metal and at least one of a group consisting of nitrogen and carbon;
forming a third metal oxide layer overlying the second intermediate layer;
providing oxygen to the first and second intermediate layers,
forming a gate overlying the third metal oxide layer;
forming a first current electrode in the semiconductor substrate; and
forming a second current electrode in the semiconductor substrate.

19. A method as in claim 18, wherein the first intermediate layer further comprise silicon and the second intermediate layer further comprises silicon.

20. A device structure, comprising:
a semiconductor substrate;
a first metal oxide layer overlying the semiconductor substrate;
a first intermediate layer overlying the first metal oxide layer, the first intermediate layer comprising a metal, oxygen, and at least one of a group consisting of nitrogen and carbon; and
a second metal oxide layer overlying the first intermediate layer.

21. A method as in claim 1, further comprising forming a gate electrode on the second metal oxide layer.
